(19) United States
(12) Patent Application Publication
(10) Pub. No.: US 2014/0367620 A1
(43) Pub. Date: Dec. 18, 2014

(54) METHOD FOR IMPROVING PATTERNED SILVER CONDUCTIVITY

(71) Applicants: Ronald Anthony Gogle, Rochester, NY (US); Thomas Edward Lowe, Mendon, NY (US); Terrence Robert O'Toole, Webster, NY (US); Michael Phillip Youngblood, Rochester, NY (US)

(72) Inventors: Ronald Anthony Gogle, Rochester, NY (US); Thomas Edward Lowe, Mendon, NY (US); Terrence Robert O'Toole, Webster, NY (US); Michael Phillip Youngblood, Rochester, NY (US)

(21) Appl. No.: 13/919,203

(22) Filed: Jun. 17, 2013

(51) Int. Cl. H05K 3/22

(52) U.S. Cl. CPC H05K 3/22
USPC 252/514; 427/58

(57) ABSTRACT

A method is used to improve the conductivity of silver disposed on a substrate. This silver is generally in the form of silver metal particles. The silver is treated with an aqueous solution comprising a conductivity enhancing agent to provide treated silver metal particles that are increased in conductivity. The treated silver metal particles are then dried. These two essential steps of treating and drying are repeated in at least one additional treatment cycle, in sequence, using the same or different conductivity enhancing agent, thereby improving the conductivity of the silver metal particles from one treatment cycle to another. This method can be carried out using an apparatus having a series of stations for carrying out each step in each treatment cycle.

### FIELD OF THE INVENTION

This invention relates to a method for enhancing the conductivity of silver that is displayed in a desired pattern, and particularly to enhancing the conductivity of silver metal particles that can be used in various conductive patterned displays. It also relates to conductive articles that contain conductive silver metal particles, as prepared using the method of this invention.

### BACKGROUND OF THE INVENTION

In recent decades accompanying rapid advances in an information-oriented society, there have also been rapid technological advances to provide devices and systems for gathering and communicating information. Display devices have been designed for television screens, commercial signage, personal and laptop computers, personal display devices, and phones of all types, to name the most common information sharing devices.

In addition, as the increase in the use of such devices has exploded in frequency and necessity by displacing older technologies, there has been a concern that electromagnetic radiation emission from such devices can cause harm to the human body or neighboring devices or instruments over time. To diminish the potential effects from the electromagnetic radiation emission, display devices are designed with various transparent conductive materials that can be used as electromagnetic wave shielding materials.

In display devices where a continuous conductive film is not practical for providing this protection from electromagnetic radiation emission, it has been found that conductive mesh or patterns can be used for this electromagnetic wave shielding purpose for example as described in U.S. Pat. No. 7,934,966 (Sasaki et al.).

Other technologies have been developed to provide new microfabrication methods to provide metallic, two-dimensional, and three-dimensional structures with conductive metals. Patterns have been provided for these purposes using photolithography and imaging through mask materials as described for example of U.S. Pat. No. 7,399,579 (Deng et al.).

In addition, as the noted display devices have developed in recent years, their attraction has increased greatly with the use of touch screen technology whereby light touches on the screen surface with a finger or stylus can create signals to cause changes in screen views or cause the reception or sending of information, telecommunications, interaction with the internet, and many other features that are being developed at an ever-increasing pace of innovation. Touch screen technology has been made possible largely by the use of transparent conductive grids on the primary display so that the location of the noted touch on the screen surface can be detected by appropriate electrical circuitry and software.

For a number of years, touch screen displays have been prepared using indium tin oxide (ITO) coatings to create arrays of capacitive patterns or areas used to distinguish multiple point contacts. ITO can be readily patterned using known semiconductor fabrication methods including photolithography and high vacuum processing. However, the use of ITO coatings has a number of disadvantages. Indium is an expensive rare earth metal and is available in limited supply. Moreover, ITO is a ceramic material and is not easily bent or flexed and such coatings require expensive vacuum deposition methods and equipment. In addition, ITO conductivity is relatively low, requiring short line lengths to achieve desired response rates (upon touch). Touch screens used in large displays are broken up into smaller segments in order to reduce the conductive line length to an acceptable electrical resistance. These smaller segments require additional driving and sensing electronics, further adding to the cost of the devices.

In other technologies, transparent polymeric films have been treated with conductive metals such as silver, copper, nickel, and indium by such methods as sputtering, ion plating, ion beam assist, wet coating, as well as the vacuum deposition. However, all of these technologies are expensive, tedious, or extremely complicated so that the relevant industries are spending considerable money to design improved means for forming conductive patterns for various devices.

Silver is an ideal conductor having conductivity that is 50 to 100 times greater than that of ITO. Unlike most metal oxides, silver oxide is still reasonably conductive and its use reduces the problem of making reliable electrical connections. Moreover, silver is used in many commercial applications and is available from numerous commercial sources.

U.S. Patent Application Publication 2011/0308846 (Ichiki) describes the preparation of conductive films formed by reducing a silver halide image in conductive networks with silver wire sizes less than 10 μm, which conductive films can be used to form touch panels in displays.

U.S. Pat. No. 7,985,527 (Tokunaga) describes the production of a conductive polymeric film by contacting the conductive metal portions with vapor or hot water.

In addition, U.S. Pat. No. 3,464,822 (Blake) describes the use of a silver halide emulsion in a photographic element to form a conductive silver surface image by development and one or more treatment baths after development.

Improvements have been proposed for providing conductive patterns using photosensitive silver salt compositions such as silver halide emulsions as described for example in U.S. Pat. No. 8,012,676 (Yoshiki et al.). Such techniques involve the treatment using hot water baths containing reducing agents or halides, but these processes have a number of disadvantages and there have been continued efforts to make additional improvements especially in conductivity.

More recently, copending and commonly assigned U.S. Ser. No. 13/771,549 (filed Feb. 20, 2013 by Sanger and Scaglione) describes the preparation of conductive silver in silver-containing films by exposing the silver-containing films to hot water vapor so that binders in the films absorb the water and conductivity is improved. Such hot water vapor can be carried out multiple times.

While transparency and conductivity for silver metal patterns can be achieved by producing very fine lines of about 5-6 μm in width, there is a need to make these thin silver conductive lines with less expensive printing and plating techniques in order to achieve a substantial improvement in cost, reliability, and availability of conductive patterns for various devices. There is a further need to increase the conductivity of the metal patterns because the conductivity achieved using silver halide films is generally insufficient for many applications such as touch screens designed for large displays such as hand-held tablets and computer monitors. The present invention addresses these needs as described in considerable detail below.

### SUMMARY OF THE INVENTION

The present invention provides a method of improving the conductivity of silver disposed on a substrate, comprising:

providing silver metal particles disposed on a substrate,

treating the silver metal particles with an aqueous solution comprising a conductivity enhancing agent to provide treated silver metal particles,

optionally washing the treated silver metal particles a different aqueous solution,

drying the treated and optionally washed silver metal particles to complete a first treatment cycle, and

repeating the treating, optional washing, and drying for at least one additional treatment cycle, in sequence, using the same or different conductivity enhancing agent, to improve the conductivity of the silver metal particles disposed on the substrate.

In some particularly useful embodiments, a method for improving the conductivity of silver metal particles, comprises:

providing an article comprising hydrophilic layer disposed on a substrate, the hydrophilic layer comprising silver metal particles within a hydrophilic binder,

advancing the article through a first set of stations including, in sequence, a first aqueous conductivity-enhancing agent station and a first drying station separated from the first aqueous conductivity-enhancing agent station, and

advancing the article from the first set of stations through a second set of stations including, in sequence, a second aqueous conductivity-enhancing agent station and a second drying station spaced from the second aqueous conductivity-enhancing agent station.

This method can further comprise:

advancing the article through a first washing station between the first aqueous conductivity-enhancing agent station and the first drying station, or

advancing the article through a second wash station between the second aqueous conductivity-enhancing agent station and the second drying station, or

both advancing the article through a first washing station between the first aqueous conductivity-enhancing agent station and the first drying station, and advancing the article through a second wash station between the second aqueous conductivity-enhancing agent station and the second drying station.

This invention thus provides conductive article comprising the silver metal particles disposed on the substrate as prepared according to any embodiment of the method of this invention. As described in more detail below, the silver metal particles in the conductive article can be provided while dispersed within a hydrophilic binder such as a hydrophilic colloid.

There are several advantages provided by the present invention. Most importantly, the silver metal disposed on the substrate and used in the conductive articles described herein has increased conductivity after the method of this invention is carried out. While various known processes involve a single treatment of coated silver metal to enhance conductivity, it has been found that multiple short treatments with the same or different treatment baths containing conductivity enhancing agents provide improved conductivity compared to use of a single long treatment. It is also critical that the treated silver metal is dried between the multiple treatments. Thus, the present invention involves the use of multiple treatment cycles, each treatment cycle comprising at least treatment with the aqueous solution comprising the conductivity enhancing agent, and drying. Washing with a different aqueous solution such as plain water can be carried out between the treating and drying features.

### BRIEF DESCRIPTION OF THE DRAWINGS

FIG. 1 is a cross sectional view of a silver-containing conductive precursor element useful in the practice of the present invention, which precursor element has an imagewise exposed and processed photographic silver halide emulsion layer on a substrate.

FIG. 2 is a cross sectional view of a silver-containing conductive precursor element useful in the practice of the present invention having printed areas of conductive silver metal.

FIG. 3 is a schematic illustration of an apparatus system that can be used to carry out the present invention, which apparatus system comprises two sets of processing stations, each processing station providing a treatment cycle comprising use of a bath for treatment with a conductivity enhancing agent and a drying station.

### DETAILED DESCRIPTION OF THE INVENTION

### Definitions

As used herein to define various components of the conductivity enhancing aqueous solutions and coating formulations, unless otherwise indicated, the singular forms “a”, “an”, and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term definition should be taken from a standard dictionary.

The use of numerical values in the various ranges specified herein, unless otherwise expressly indicated otherwise, are considered to be approximations as though the minimum and maximum values within the stated ranges were both preceded by the word “about”. In this manner, slight variations above and below the stated ranges can be used to achieve substantially the same results as the values within the ranges. In addition, the disclosure of these ranges is intended as a continuous range including every value between the minimum and maximum values.

Unless otherwise indicated, the term “weight %” refers to the amount of a component or material based on the total solids of a composition, formulation, solution, or layer. Unless otherwise indicated, the percentages can be the same for either a dry layer or pattern, or for the total solids of the formulation or composition used to make that layer or pattern.

Unless otherwise indicated, the term “article”, “element”, and “conductive article” are intended to mean the same thing. They refer to the materials containing the silver metal particles disposed on a suitable substrate.

Other components of the article or element are described below.

A “precursor element” is meant to refer to an article or element that is used to provide the conductive article or conductive element of the present invention. Such precursor elements therefore comprise a precursor to the silver metal particles, such as a silver salt as described below that is suitably converted (for example by reduction) to silver metal. Much of the discussion about precursor elements is equally applicable to the conductive articles or conductive elements of the present invention as most of the components of the precursor elements are not changed when silver cations in a silver salt are converted to silver metal. Thus, unless otherwise indicated, the discussion of substrates, hydrophilic binders and colloids, and other addenda in silver salt layers for the precursor elements are also intended to describe the components of the resulting articles or elements.

Unless otherwise indicated, the terms “conductive article”, “conductive element”, and “conductive film” are refer to embodiments of the present invention

### Uses

The method of this invention can be used in many ways to form a conductive silver metal pattern on a suitable or substrate to form conductive articles that can be used as devices themselves or be used as components for devices in a variety of applications including but not limited to, electronic, optical, sensory, and diagnostic devices. More details of such uses are provided below. In particular, it is desired to use the present invention to provide highly conductive silver metal patterns comprising lines having a line resolution (line width) of less than 50 μm, or less than 15 μm, or even less than 10 μm and as low as 1 μm.

Such electronic and optical devices and components include but are not limited to, radio frequency tags (RFID), sensors, touch screen displays, and memory and back panel displays. The method of this invention can be used to form patterns of electrically conductive silver metal patterns and conductive films. The conductive silver metal patterns and conductive films can be designed to be temperature-sensitive or pressure-sensitive as well.

The present invention is also useful for providing electrically conductive patterns on substrates, such as in conductive films that are designed for use as touch panel displays.

### Conductive Articles

Conductive articles of the present invention can be prepared using silver, for example, in the form of silver metal particles, disposed on a suitable substrate in a suitable precursor element. The silver metal in this precursor element is then treated using more than one treatment cycles as described below to improve conductivity of the silver metal beyond its inherent conductive property.

Precursor elements (for example, precursor silver metal-containing films) can be formed by providing silver metal particles of the substrate in a suitable manner. In general, the silver metal particles are provided from suitable silver cations in a silver salt as described below that is incorporated into a precursor element while dispersed within one or more suitable hydrophilic binders or colloids as described below also. Such precursor elements are therefore treated in such a manner as to convert the silver cations (such as by reduction) into silver metal, and the precursor element can then become a conductive article of the present invention after appropriate treatment. Alternatively, the precursor element can be treated in a suitable manner as to convert the silver cations into silver metal, and this silver metal is then removed from the precursor element and incorporated onto another substrate that is then treated to form a conductive article of the present invention.

Substrates:

While silver metal particles can be provided in a number of ways, including vapor deposition, plating, electroplating, deposition of a silver metal-containing dispersion, and a particularly useful way to provide silver metal particles is to reduce silver cations that are part of a silver salt that can be in a coated layer or dispersion (for example, emulsion). In such embodiments, the silver salts are generally disposed in a suitable manner on a substrate. The choice of substrate generally depends upon the intended utility of the resulting conductive article, and can be any substrate on which a conductive silver film, grid, or pattern is desired. It can be rigid or flexible, opaque or transparent, depending upon the use. For example, the substrate can be a transparent, flexible substrate. Suitable substrates include, but are not limited to, glass, glass-reinforced epoxy laminates, cellulose triacetate, acrylic esters, polycarbonates, adhesive-coated polymer substrates, polymer substrates, and composite materials. Suitable polymers for use as polymer substrates include polyethylenes, especially polyethylene terephthalate (PET) and polyethylene naphthalate (PEN), polypropylenes, polyvinyl acetates, polyurethanes, polyesters, polyamides, polyimides, polysulfones, and mixtures thereof. Polymeric substrates can also comprise two or more layers of the different or same polymeric composition so that the composite substrate has various refractive properties. The substrate can be treated to improve adhesion of a silver salt emulsion or dispersion to one or both surfaces of the substrate. For example, the substrate can be coated with a polymer adhesive layer or one or both surfaces can be chemically treated or subjected to a corona treatment.

Commercially available oriented and non-oriented polymer films, such as opaque biaxially oriented polypropylene or polyester, can also be used. Such substrates can contain pigments, air voids or foam voids to enhance opacity if desired. The substrate can also comprise microporous materials such as polyethylene polymer-containing material sold by PPG Industries, Inc., Pittsburgh, Pa. under the trade name of Teslin®, Tyvek® synthetic paper (DuPont Corp.) and other composite films listed in U.S. Pat. No. 5,244,861 the disclosure of which is incorporated herein by reference. Useful composite sheets are disclosed in, for example, U.S. Pat. No. 4,377,616 (Ashcraft et al.), U.S. Pat. No. 4,758,462 (Park et al.), and U.S. Pat. No. 4,632,869 (Park et al.), the disclosures of which are incorporated herein by reference.

The substrate can be voided, which means voids formed from added solid and liquid matter, or “voids” containing gas. The void-initiating particles, which remain in the finished packaging sheet core, should be from at least 0.1 and up to and including 10 μm in diameter and typically round in shape to produce voids of the desired shape and size. Micro voided polymeric films are particularly useful in some embodiments. For example, some commercial products having these characteristics that can be used as support are commercially available as 350K18 from ExxonMobil and KTS-107 (from HSI, South Korea).

Biaxially oriented sheets, while described as having at least one layer, can also be provided with additional layers that can serve to change the properties of the biaxially oriented sheet. Such layers might contain tints, antistatic or conductive materials, or slip agents to produce sheets of unique properties. The biaxially oriented extrusion can be carried out with as many as 10 layers if desired to achieve some particular desired property. The biaxially oriented sheet can be made with layers of the same polymeric material, or it can be made with layers of different polymeric composition.

Useful transparent substrates can be composed of glass, cellulose derivatives, such as a cellulose ester, cellulose triacetate, cellulose diacetate, cellulose acetate propionate, cellulose acetate butyrate, polyesters, such as poly(ethylene terephthalate), poly(ethylene naphthalate), poly-1,4-cyclohexanedimethylene terephthalate, poly(butylene terephthalate), and copolymers thereof, polyimides, polyamides, polycarbonates, polystyrene, polyolefins, such as polyethylene or polypropylene, polysulfones, polyacrylates, polyether imides, and mixtures thereof. The term as used herein, “transparent” means that the substrate has greater than 50% light transmission to visible light of 450 nm to 750 nm.

Useful substrates for the manufacture of flexible electronic devices or components can be flexible, which aids rapid roll-to-roll application. Estar® poly(ethylene terephthalate) films and cellulose triacetate films are particularly useful materials for making flexible transparent substrates.

The substrate can be the same as a support that is already incorporated into a flexible display device, by which it is meant that a silver salt (described below) can be applied to a support within a display device and imaged in situ according to a desired pattern, and then processed in situ.

Where a discrete substrate is utilized (that is, the substrate is not already incorporated in a flexible display device), a silver salt layer can be applied to one or both sides thereof. If different patterns are intended for each side, the substrate or intervening layers of absorber dyes can be provided to prevent light exposure from one side reaching the other. Alternatively, the silver salts can be sensitized differently for each side of the substrate.

The substrate used in the precursor element can have a thickness of at least 50 μm and up to and including 180 μm or typically at least 75 μm and up to and including 125 μm, depending upon the intended use in the conductive article. Antioxidants, brightening agents, antistatic or conductive agents, plasticizers and other known additives can be incorporated into the substrate, if desired.

Silver Salts and Silver Salt Layers:

The silver cations of a silver salt that can be converted into silver metal can be any material that is capable of providing a latent image (that is, a germ or nucleus of silver metal in each exposed grain of silver salt) according to a desired pattern upon photo-exposure or thermal exposure. The latent image can then be developed into a silver metal image using known silver development procedures and chemistry. In most embodiments, the silver salt (or combination of silver salts) is photosensitive, meaning that radiation from UV to visible light (for example, from at least 100 nm and up to and including 750 nm radiation) is generally used to convert silver cations to silver metal. However, in other embodiments, the silver salt (or combination of silver salts) can be thermally sensitive, such as in the near infrared or infrared regions of the electromagnetic spectrum, for example at least 700 nm and up to and including 1500 nm. In still other embodiments, the silver salt (or combination of silver salts) can be both photosensitive and thermally sensitive.

In many embodiments, the useful silver salt is a photosensitive silver salt such as a silver halide or mixture of silver halides. The silver halide can be, for example, silver chloride, silver bromide, silver chlorobromoiodide, silver chlorobromide, or silver bromoiodide. In one useful embodiment, the silver halide grains (and any addenda associated therewith) are dispersed in one or more suitable hydrophilic binders or colloids to form a silver halide emulsion. Some silver halide emulsions are known as high contrast silver halide emulsions such as a silver chlorobromide emulsion comprising for example, at least 50 mol % silver chloride, typically at least 60 mol % and up to and including 90 mol % silver chloride. The remainder of the silver halide can be substantially silver bromide and optionally comprise a small amount (for example, up to 2 mol %) of silver iodide. These percentages are in reference to the total halide in the silver salts.

As noted, the silver salt can be dispersed in a silver salt layer that comprises one or more hydrophilic binders or colloids. Examples of such hydrophilic binders or colloids include but are not limited to, hydrophilic colloids such as gelatin and gelatin derivatives, polyvinyl alcohol (PVA), poly(vinyl pyrrolidone) (PVP), casein, and mixtures thereof. Suitable hydrophilic colloids and vinyl polymers and copolymers are also described in Section IX of Research Disclosure Item 36544, September 1994 that is published by Kenneth Mason Publications, Emsworth, Hants, P010 7DQ, UK. A particularly useful hydrophilic colloid is gelatin or a gelatin derivative of which several are known in the art.

In some embodiments, the hydrophilic binder used in a silver salt layer (or any other layer) is used in combination with one or more hardeners designed to harden the particular hydrophilic binder such as gelatin. Particularly useful hardeners for gelatin and gelatin derivatives include but are not limited to, non-polymeric vinyl-sulfones such as bis(vinyl-sulfonyl) methane (BVSM), bis(vinyl-sulfonyl methyl)ether (BVSME), and 1,2-bis(vinyl-sulfonyl acetoamide)ethane (BVSAE). Mixtures of hardeners can be used if desired.

One useful photosensitive silver salt composition is a high silver metal/low hydrophilic binder (for example, gelatin) composition, which after silver salt development, is sufficiently conductive. When the silver salt layer comprises silver halide grains dispersed in gelatin or a gelatin derivative, a particularly useful weight ratio of silver ions to gelatin (or derivative) is at least 1.5:1. In certain embodiments, this ratio can be at least 2:1 and up to and including 3:1.

In many embodiments, the useful silver salt described above is sensitized to any suitable wavelength of exposing radiation. Organic sensitizing dyes can be used, but it can be advantageous to sensitize the silver salt to the UV portion of the electromagnetic spectrum without using visible light sensitizing dyes to avoid unwanted dye stains if the article containing the silver metal particles is intended to be transparent.

Non-limiting examples of silver halide emulsions useful in the present invention, including addenda and hydrophilic binders or colloids are described in Research Disclosure Item 36544, September 1994 and the many publications identified therein. Such materials are well known in the art and would not be difficult for a skilled artisan to formulate or use for purposes described herein. Other useful silver salt emulsions are also described, for example in U.S. Pat. No. 7,351,523 (Grzeskowiak); U.S. Pat. Nos. 5,589,318 and 5,512,415 (both to Dale et al.), the disclosures of all of which are incorporated herein by reference.

Useful silver halide emulsions containing silver halide grains that can be reduced to silver metal particles can be prepared by any suitable method of grain growth, for example, by using a balanced double run of silver nitrate and salt solutions using a feedback system designed to maintain the silver ion concentration in the growth reactor. Known dopants can be introduced uniformly from start to finish of precipitation or can be structured into regions or bands within the silver halide grains. Useful dopants include but are not limited to osmium dopants, ruthenium dopants, iron dopants, rhenium dopants, iridium dopants, and cyanoruthenate dopants. A combination of osmium and iridium dopants such as osmium nitrosyl pentachloride is useful. Such complexes can be alternatively utilized as grain surface modifiers in the manner described in U.S. Pat. No. 5,385,817 the disclosure of which is incorporated herein by reference. Chemical sensitization can be carried out by any of the known silver halide chemical sensitization methods, for example using thiosulfate or another labile sulfur compound, or in combination with gold complexes.

Useful silver halide grains can be cubic, octahedral, rounded octahedral, polymorphic, tabular, or thin tabular emulsion grains. Such silver halide grains can be regular untwinned, regular twinned, or irregular twinned with cubic or octahedral faces. In one embodiment, the silver halide grains are cubic having an edge length of less than 0.5 μm and at least 0.05 μm.

Specific references relating to the preparation of emulsions of differing halide ratios and morphologies are U.S. Pat. No. 3,622,318 (Evans); U.S. Pat. No. 4,269,927 (Atwell); U.S. Pat. No. 4,414,306 (Wey et al.); U.S. Pat. No. 4,400,463 (Maskasky); U.S. Pat. No. 4,713,323 (Maskasky); U.S. Pat. No. 4,804,621 (Tufano et al.); U.S. Pat. No. 4,783,398 (Takada et al.); U.S. Pat. No. 4,952,491 (Nishikawa et al.); U.S. Pat. No. 4,983,508 (Ishiguro et al.); U.S. Pat. No. 4,820,624 (Hasebe et al.); U.S. Pat. No. 5,264,337 (Maskasky); U.S. Pat. No. 5,275,930 (Maskasky); U.S. Pat. No. 5,320,938 (House et al.); U.S. Pat. No. 5,550,013 (Chen et al.); U.S. Pat. No. 5,726,005 (Chen et al.); and U.S. Pat. No. 5,736,310 (Chen et al.), the disclosures of all of which are incorporated herein by reference.

Antifoggants and stabilizers can be added to give the silver halide emulsion the desired sensitivity, if appropriate. Antifoggants that can be used include, for example, azaindenes such as tetraazaindenes, tetrazoles, benzotriazoles, imidazoles and benzimidazoles. Specific antifoggants that can be used include 5-carboxy-2-methylthio-4-hydroxy-6-methyl-1,3,3a,7-tetraazaindene, 1-(3-acetamidophenyl)-5-mercaptotetrazole, 6-nitrobenzimidazole, 2-methylbenzimidazole, and benzotriazole, individually or in combination.

Nucleators and development boosters can be used to give ultra-high contrast. For example, combinations of hydrazine nucleators such as those disclosed in U.S. Pat. No. 6,573,021 (Baker et al.), or hydrazine nucleators disclosed in U.S. Pat. No. 5,512,415 (Dale et al., Col. 4, line 42 to Col. 7, line 26) can be used, the disclosures of both references being incorporated herein by reference. Booster compounds that can be present include amine boosters that comprise at least one secondary or tertiary amino group and have an n-octanol/water partition coefficient (log P) of at least 1, for example of at least 3. Any nucleator or booster compound utilized can be incorporated into the silver halide emulsion, or alternatively can be present in a hydrophilic colloid layer that is adjacent the layer containing the silver halide emulsion for which the effects of the nucleator are intended.

In other useful embodiments, a combination of silver salts in the precursor element provides sensitivity to both exposing radiation and heat, and can be known as “photothermographic” silver salt compositions. Such photothermographic compositions can comprise a silver halide in combination with a source of non-photosensitive reducible silver ions such as in organic silver salts (for example silver salts of aliphatic fatty acids). Such photothermographic silver salt compositions are described for example in U.S. Pat. No. 7,482,113 (Simpson et al.), U.S. Pat. No. 6,342,343 (Toya), and U.S. Pat. No. 6,645,714 (Oya et al.), the disclosures of which are incorporated herein by reference. Many other publications are available to provide further details of such photothermographic silver salt compositions.

Still other useful embodiments include the use of silver salt compositions that are essentially non-photosensitive but in which a silver salt is present that is thermally sensitive and can be reduced to silver metal primarily by heating or thermal energy only. Such silver salt compositions are generally known as “thermographic” silver salt compositions that can include one or more organic silver salts, for example as described in U.S. Pat. No. 6,093,528 (Terrill et al.) the disclosure of which is incorporated herein by reference. Many other publications are available that provide further details of such thermographic silver salt compositions.

Additional Layers:

In addition to layer(s) containing a silver salt disposed on a substrate, the precursor elements useful in the present invention can include other layers such as overcoat layers, light absorbing filter layers, adhesion layers, and other layers as are known in the photographic art. For example, light absorbing filter layers can include one or more filter dyes that absorb in the UV, red, green, or blue regions of the electromagnetic spectrum, or any combination thereof.

In embodiments wherein a silver salt layer is provided on both sides of a substrate and each silver salt layer is exposed with radiation of a unique wavelength, it is useful to provide a light absorbing filter layer comprising a filter dye between each silver salt layer and the substrate on one or both sides, whereby the filter dye is chosen to absorb specific exposing radiation.

In many useful embodiments, the silver cation coverage in the precursor elements is at least 1000 mg/m² and the silver cation to hydrophilic binder (for example, gelatin) weight ratio in the silver salt layer is at least 1.5:1.

When silver metal particles are formed for example in a pattern or grid, such conditions result in silver metal lines that are significantly raised relative to the non-imaged hydrophilic binder (or gelatin) background on the substrate. In most embodiments, the conductive articles are transparent (meaning greater than 50% light transmission to visible light of 450 nm to 750 nm) using thin grid lines of silver metal particles (for example, each silver metal line less than 10 μm wide), the amount of hydrophilic binder (or gelatin) can be less than noted above.

### Providing Silver Metal Particles

The precursor elements can be used to provide conductive articles comprising silver metal particles in any suitable manner that converts silver ions in an imagewise exposed photosensitive silver-containing salt layer on a substrate into silver metal particles. Generally, this requires reduction (development) of the silver cations in the silver salts to silver metal in any suitable manner. This invention is not limited to the technique used for development (or silver ion reduction), but the aqueous solution development described below is typically used and described as a non-limiting embodiment. In any of these techniques, the silver metal particles can be disposed on the substrate in a predetermined pattern, and they are generally dispersed within a hydrophilic binder or colloid as described herein to form a conductive film in the precursor element that is made even more conductive using the method of the present invention.

For example, the photothermographic and thermographic silver salt compositions described above can be “developed” using thermal energy (heat) to convert silver cations to silver metal in an imagewise fashion to form silver metal particles in a predetermined grid or pattern.

More commonly, photosensitive silver salts disposed in a precursor element can be imagewise exposed to appropriate actinic radiation (UV to visible) and developed (silver ions reduced) using known aqueous developing solutions that are commonly used in black-and-white photography.

Numerous developing solutions (identified herein also as “developer”) are known that can develop the exposed silver salts described above to form silver metal, for example in the form of a grid or pattern. It has been found, that commercially available developers do not also provide conductivity across the grid pattern that is desired. While these commercial developers can be used, in many embodiments, unique developers have been formulated to improve silver metal conductivity. One commercial developer that provides some conductivity is Accumax® silver halide developer when it is used to develop exposed silver chlorobromide grains such as those used in graphic arts.

Developers are generally aqueous solutions including one or more silver salt (such as a silver halide) developing agents, of the same or different type, including but not limited to those described in Research Disclosure Item 17643 (December, 1978) Item 18716 (November, 1979), and Item 308119 (December, 1989) such as polyhydroxybenzenes (such as dihydroxybenzene, or in its form as hydroquinone, cathecol, pyrogallol, methylhydroquinone, and chlorohydroquinone), aminophenols such as p-methylaminophenol, p-aminophenol, and p-hydroxyphenylglycine, p-phenylenediamines, ascorbic acid and its derivatives, reductones, erythrobic acid and its derivatives, 3-pyrazolidones such as 1-phenyl-4,4-dimethyl-3-pyrazolidone, 1-phenyl-3-pyrazolidone, and 1-phenyl-4-methyl-4-hydroxymethyl-3-pyrazolidone, pyrazolone, pyrimidine, dithionite, and hydroxylamines. These developing agents can be used individually or in combinations thereof. One or more developing agents can be present in an amount of at least 0.001 mol/l and up to and including 5 mol/l, or typically in an amount of at least 0.005 mol/l and up to and including 1 mol/1.

The developers can also include auxiliary silver developing agents that exhibit super-additive properties with a developing agent. Such auxiliary developing agents can include but are not limited to, Elon and substituted or unsubstituted phenidones, in an amount of at least 0.0001 mol/l and up to and including 0.02 mol/l, or typically in an amount of at least 0.001 mol/l and up to and including 0.005 mol/1.

Useful developers can also include one or more silver complexing agents (or silver ligands) including but not limited to, sulfite, thiocyanate, thiosulfate, thiourea, thiosemicarbazide, tertiary phosphines, thioethers, amines, thiols, aminocarboxylates, triazolium thiolates, pyridines (including bipyridine), imidazoles, and aminophosphonates. The useful amount of one or more silver complexing agents is at least 0.05 g/l and up to and including 2.0 g/l.

Other addenda that can be present in the developers in amounts that would be readily known, include but are not limited to, metal chelating agents, preservatives (such as sulfites), antioxidants, small amounts of water-miscible organic solvents (such as benzyl alcohol and diethylene glycol), nucleators, and acids, bases (such as alkali hydroxides), and buffers (such as carbonate, borax, phosphates, and other basic salts) to establish a pH of at least 8 and generally of a pH of at least 9.5, or at least 11 and up to and including 14. Multiple development steps can be used if desired. For example, a first developer can provide initial development and then a second developer that has higher silver salt solubilizing power can be used to provide “solution physical development”.

Useful developer temperatures can range from at least 15° C. and up to and including 50° C., and more typically from at least 25° C. and up to and including 40° C. Useful development times are in a range from at least 10 seconds and up to and including 10 minutes and typically from at least 20 seconds and up to and including 5 minutes.

The developers can also comprise one or more substituted or unsubstituted mercaptotetrazoles in suitable amounts for various purposes. Useful mercaptotetrazoles include but are not limited to, alkyl-, aryl-, and heterocyclyl-substituted mercaptotetrazoles. Examples of such compounds include but are not limited to, 1-phenyl-5-mercaptotetrazole (PMT), 1-ethyl-5-mercaptotetrazole, 1-t-butyl-5-mercaptotetrazole, and 1-pyridinyl-5-mercaptotetrazoles.

The developers can also include one or more development inhibitors in suitable amounts. Useful development inhibitors include but are not limited to, substituted and unsubstituted benzotriazole compounds such as 5-methylbenzotriazole, imidazoles, benzimidazole thiones, benzathiazole thiones, benzoxazole thiones, and thiazoline thiones.

Prebath solutions can also be used to treat the exposed silver salts prior to development. Such solutions can include one or more development inhibitors as described above for the developers, and in the same or different amounts. Effective inhibitors for use in the prebath include benzotriazoles, heterocyclic thiones, and mercaptotetrazoles. The prebath temperature can be in a range as described for the developer. Prebath time depends upon concentration and the particular inhibitor, but the time can range from at least 10 seconds and up to and including 4 minutes.

In some embodiments, extended development times, with or without a prebath can be useful. For example, the development time does not extend generally more than 60 seconds more than the time it takes to develop 90% of the silver cations in the exposed areas.

After development, the undeveloped silver salt is generally removed by treating the developed silver-containing article with a fixing solution. Fixing solutions are well known in the photographic art and contain compounds that complex the silver salt in order to dissolve it out of the binder. Thiosulfate salts are commonly used in fixing solutions. The fixing solution can optionally contain a hardening agent such as alum or chrome-alum. The developed film can be processed in a fixing solution immediately after development, or there can be an intervening stop bath or water wash or both. A stop bath typically contains a dilute acid such as acetic or sulfuric acid and has a pH of less than 5. After fixing, the silver-containing article can be washed in water which can optionally include surfactants or other materials to reduce water spot formation upon drying. Drying can be conducted simply by drying in air or by heating, for example, in a convection oven. Heating at a temperature above 80° C. but below the glass transition temperature of the support, can also be carried out.

### Conductivity Enhancement Treatment Cycles

Once the silver metal particles are generated using any of the procedures described above, the method of the present invention includes treating those silver metal particles using two or more treatment cycles wherein each treatment cycle has two essential components: (1) treatment using an aqueous solution comprising a conductivity enhancing agent, and (2) drying. It is particularly desired to use two or more additional treatment cycles beyond the first treatment cycle to enhance the conductivity of the silver metal particles and to provide the conductive article of this invention.

Each treatment cycle can further include washing of the treated silver metal particles with an aqueous solution (such as plain water) before drying. This aqueous solution is different from that used to include the conductivity enhancing agent. This washing is not essential, but can be very desirable in many embodiments. After the first treatment cycle, generally at least one or two additional treatment cycles are carried out using the same or different conductivity enhancing agent in the aqueous solution. Up to ten of these additional treatment cycles can be carried out if desired but typically only one or two additional treatment cycles are used after the first treatment cycle.

In each treatment cycle, the aqueous solution comprising one or more conductivity enhancing agents is generally contacted with the silver metal particles in a suitable manner, such as spraying, coating, immersion into a bath, or other application method that would be readily apparent to one skilled in the art. This aqueous solution is generally used at a temperature of at least room temperature or more likely at least 30° C. and up to and including 90° C., or typically of at least 45° C. and up to and including 80° C. or even at least 50° C. and up to and including 70° C. The temperature can be the same or different for each of the two or more treatment cycles.

Each treatment of the silver metal particles with such an aqueous solution is generally carried out for at least 0.25 minute and up to and including 30 minutes or more likely at least 1 minute and up to and including 20 minutes, but a particularly useful treatment time for each treatment cycle is at least 1 minute and up to and including 4 minutes so that each treatment is relatively short. The treatment times can be the same or different for the two or more treatment cycles. In some embodiments, the treatment in the initial treatment cycle is longer than the treatment in the successive treatment cycle(s).

Useful conductivity enhancing agents for these aqueous solutions include but are not limited to, one or more sulfites (such as sodium sulfite, potassium sulfite, and ammonium sulfite), borane compounds (such as dimethylamine borane, t-butylamine borane, and borane tetrahydrofuran), hydroquinones (such as hydroquinone, naphthohydroquinone and hydroxyquinol), p-phenylenediamines (such as p-phenylenediamine, N,N-diethyl-1,4-benzenediamine, and N-ethyl, N-hydroxyethyl-1,4-benzenediamine), or phosphites (including both inorganic and organic phosphites such as sodium phosphite, sodium hypophosphite, and trimethyl phosphite). These compounds can be used singly or in combination, and their total concentration in the aqueous solution is at least 0.1 weight % and up to and including 2.5 weight %, or typically at least 0.5 weight % and up to and including 1.5 weight %.

The aqueous solution comprising the one or more conductivity enhancing agents generally has a pH of at least 6 and up to and including 11, or typically a pH of at least 8.5 and up to and including 10.5. The pH can be adjusted using a suitable alkaline compound (such as a hydroxide) and any suitable buffer can be included to maintain the desired pH, as long as these additional components do not detract from the desired effect of the conductivity enhancing agents.

In addition to the essential conductivity enhancing agents described above, the aqueous solution can include one or more optional components for various purposes including but not limited to, surfactants, defoaming agents, antiseptic agents, biocides, or a primary or secondary organic amine compound (such as 1,2-bis(3-aminopropylamino)ethane). Each of these compounds can be present in an amount of at least 0.1 weight % and up to and including 2.5 weight %.

When the treated silver metal particles are washed before the essential drying, they are washed with an aqueous solution such as tap or purified water at a temperature of at least 20° C. and up to and including 90° C., or typically of at least 30° C. and up to and including 50° C. This aqueous solution for washing is different from those aqueous solutions containing a conductivity enhancing agent. However, these aqueous washing solutions can have small amounts of known surfactants, defoaming agents, antiseptic agents, or biocides. This aqueous solution does not purposely contain a conductivity enhancing agent. The time for washing can be at least 30 seconds and up to and including 5 minutes, and the time and temperature can be adjusted with routine experimentation depending upon the precursor element and apparatus used for the method. The time and temperature for each washing step can be the same or different for each treatment cycle. While washing is optional and can be used in some but not all treatment cycles, in many embodiments it is desired to use washing in the initial treatment cycle and all additional treatment cycles using the same or different aqueous solution. In other embodiments, only the last additional treatment cycle includes a washing step between the aqueous solution treatment and drying.

After the initial treatment with the aqueous solution and optional washing, the treated and optionally washed silver metal particles are dried in a suitable manner. For example, the silver metal particles can be dried by blowing relatively dry air or insert gas over the treated and washed silver metal particles or by heating to a suitable temperature, or combinations thereof. The desired drying conditions would be readily determined by a skilled artisan with routine experimentation. In most embodiments, drying is carried out by blowing heated air over the treated and washed silver metal particles using temperature and time conditions that are adjusted in order to remove at least 90% or more likely at least 95% of any residual fluid in the layer containing the silver metal particles disposed on the substrate in a reasonable time. Thus, the drying temperature can be at least 40° C. and up to but less than the glass transition temperature of the substrate on which the silver particles are disposed, for example, less than 140° C. Infrared radiation can also be used for drying the treated and washed silver metal particles.

In some embodiments, the method of the present invention for improving the conductivity of silver metal particles, comprises:

providing an article comprising a hydrophilic layer disposed on a substrate, the hydrophilic layer comprising silver metal particles within a hydrophilic binder,

advancing the article through a first set of stations including, in sequence, a first aqueous conductivity-enhancing agent station and a first drying station separated from the first aqueous conductivity-enhancing agent station, and

advancing the article from the first set of stations through a second set of stations including, in sequence, a second aqueous conductivity-enhancing agent station and a second drying station spaced from the second aqueous conductivity-enhancing agent station.

This sequence would complete at least two treatment cycles because each set of stations includes a treatment cycle. In is also possible to include washing stations between each of the aqueous conductivity-enhancing agent station and each sequential drying station.

For example, this method can further comprise:

advancing the article through a first washing station between the first aqueous conductivity-enhancing agent station and the first drying station, or

advancing the article through a second wash station between the second aqueous conductivity-enhancing agent station and the second drying station, or

both advancing the article through a first washing station between the first aqueous conductivity-enhancing agent station and the first drying station, and advancing the article through a second wash station between the second aqueous conductivity-enhancing agent station and the second drying station.

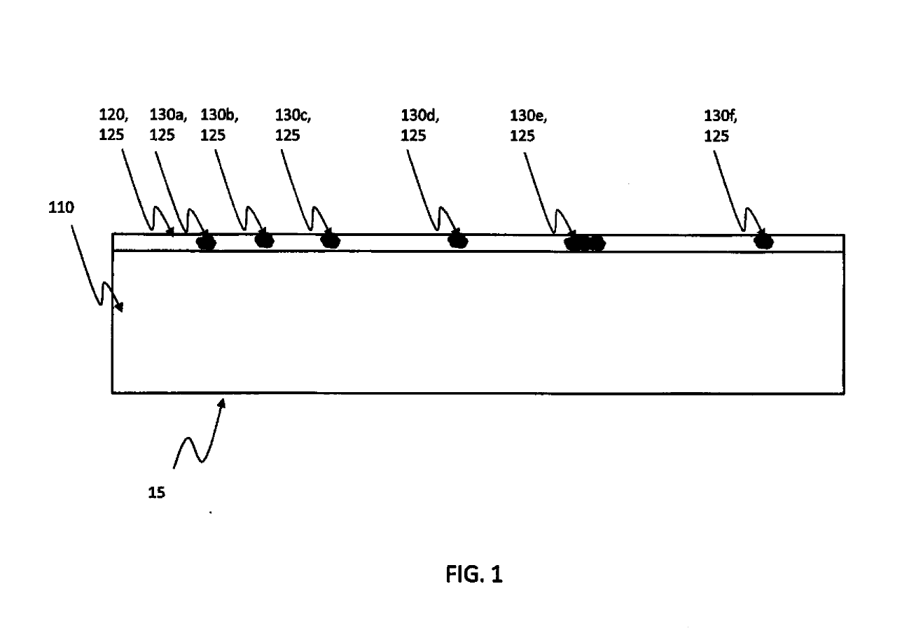

Referring to FIGS. 1-3 that illustrate particular embodiments of the present invention:

FIG. 1 is a cross section of an exposed and processed silver-containing precursor element 15. In this embodiment, the exposed and processed silver-containing precursor element 15 includes substrate 110 with an imagewise exposed and processed photographic silver halide emulsion layer 120 comprising hydrophilic binder 125 and conductive traces 130a-f that comprise small metallic silver nanoparticles mixed with hydrophilic binder 125.

Substrate 110 can be composed of a glass, cellulosic paper, plastic or polymer such as poly(ethylene terephthalate), metal, or another suitable material, or combination of materials. Substrate 110 can have other layers that are not shown in FIG. 1 and substrate 110 can have other functionality. For example, substrate 110 can optionally be folded, cut, embossed, or otherwise manipulated as needed.

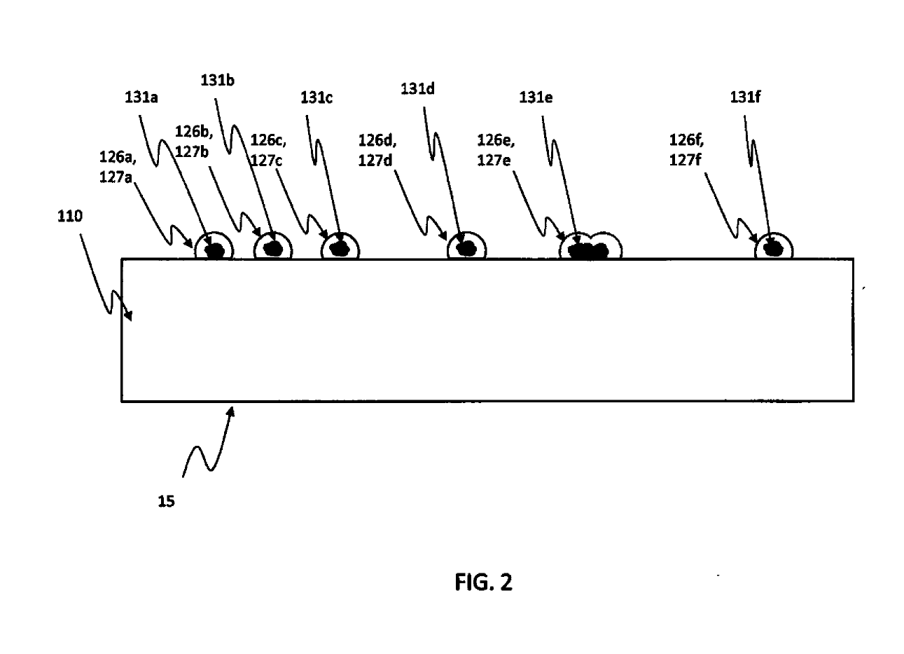

FIG. 2 is a cross section of another embodiment of an imagewise exposed and processed silver-containing precursor element 15. In this embodiment, silver-containing precursor element 15 includes substrate 110 with printed areas 127a-f of a conductive material comprising both hydrophilic binder 126a-f, respectively, and conductive silver metal nanoparticles 131a-f, respectively, mixed with hydrophilic binder 126a-f, respectively.

Printed areas 127a-f can be provided on substrate 110 using a variety of printing techniques including but not limited to, inkjet, flexography, intaglio printing, screen printing, thermal or laser transfer, offset lithographic printing, pad printing, stamp printing, gravure printing or any other suitable printing method.

In one embodiment, printed areas 127a-f can be a composed of a silver ink comprising conductive silver metal nanoparticles 131a-f provided in hydrophilic binder 126a-f. In another embodiment, silver metal precursor materials (for example, silver salts) can be printed and then processed to form the desired conductive silver metal nanoparticles 131a-f. For example, one can print a photographic silver halide emulsion that can then be exposed using any masked or unmasked light source, and processed to form conductive silver metal nanoparticles 131a-f in a gelatin as the hydrophilic binder 126a-f.

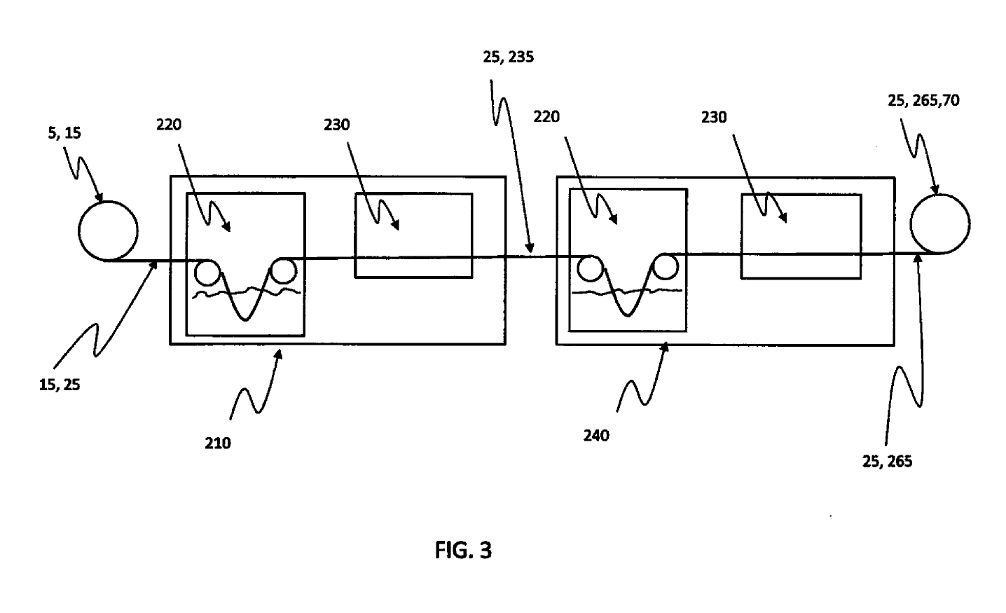

FIG. 3 illustrates an embodiment using multiple treatment cycles. Thus, FIG. 3 shows first set of stations 210, and second set of stations 240. Each set of stations contains bath treatment station 220 containing an aqueous solution comprising a conductivity enhancing agent followed by drying station 230. A roll of exposed and processed silver-containing precursor element 15 is loaded into supply spool 5. Web 25 of exposed and processed silver-containing precursor element 15 brought into first set of stations 210 where it passes through bath treatment station 220 followed by drying station 230 and exits first set of stations 210 as web 25 of treated conductive silver-containing element 235. Web 25 of treated conductive silver-containing element 235 then it brought into second set of stations 240 where it passes through bath treatment station 220 containing the same or different conductivity enhancing agent, followed by drying station 230 and exists as web 25 of additionally treated conductive silver-containing element 265. Web 25 of additionally treated conductive silver-containing element 265 is then wound onto take-up spool 70 and is then ready for use as an article of the present invention and for incorporation into various devices as desired. Thus, the use of first set of stations 210 and second set of stations 240 comprises an initial treatment cycle and a single additional treatment cycle according to the present invention.

It is contemplated that first set of stations 210 and second set of stations 240 can be one physical unit and web 25 can be passed through either first set of stations 210 or second set of stations 240, or both sets of stations, multiple times to provide multiple treatment cycles.

It is also contemplated that one or more additional set of stations can be placed in line besides those illustrated in FIG. 3, and web 25 can be subjected to more than two treatment cycles. It will be recognized by a skilled artisan that the duration (time) and temperature of each bath treatment station, the length (time) and temperature within each drying station, and the speed of web 25 can be adjusted to optimize the present invention using routine experimentation with the teaching provided herein. The adjustments can be dependent upon the number of treatment cycles and the particular precursor element that is used in the method.

It is also contemplated that the present invention can be carried out according to FIG. 3 to continuous webs or rolls of precursor elements as well treat cut sheets of precursor elements by moving individual sheets through the first and second set of stations on a belt or a conveyor means. It will also be understood that the present invention can be carried out with cut individual sheets of precursor elements and moving each sheet through a single first set of stations multiple times.

The present invention provides at least the following embodiments and combinations thereof, but other combinations of features are considered to be within the present invention as a skilled artisan would appreciate from the teaching of this disclosure:

1. A method of improving the conductivity of silver disposed on a substrate, comprising:

providing silver metal particles disposed on a substrate,

treating the silver metal particles with an aqueous solution comprising a conductivity enhancing agent to provide treated silver metal particles,

optionally washing the treated silver metal particles with a different aqueous solution,

drying the treated and optionally washed silver metal particles to complete a first treatment cycle, and

repeating the treating, optional washing, and drying for at least one additional treatment cycle, in sequence, using the same or different conductivity enhancing agent, to improve the conductivity of the silver metal particles disposed on the substrate.

2. A method for improving the conductivity of silver metal particles, comprising:

providing an article comprising a hydrophilic layer disposed on a substrate, the hydrophilic layer comprising silver metal particles dispersed within a hydrophilic binder,

advancing the article through a first set of stations including, in sequence, a first aqueous conductivity-enhancing agent station and a first drying station separated from the first aqueous conductivity-enhancing agent station, and

advancing the article from the first set of stations through a second set of stations including, in sequence, a second aqueous conductivity-enhancing agent station and a second drying station spaced from the second aqueous conductivity-enhancing agent station.

3. The method of embodiment 2, further comprising:

advancing the article through a first washing station between the first aqueous conductivity-enhancing agent station and the first drying station, or

advancing the article through a second wash station between the second aqueous conductivity-enhancing agent station and the second drying station, or

both advancing the article through a first washing station between the first aqueous conductivity-enhancing agent station and the first drying station, and advancing the article through a second wash station between the second aqueous conductivity-enhancing agent station and the second drying station.

4. The method of embodiment 2 and 3, further comprising:

both advancing the article through a first washing station between the first aqueous conductivity-enhancing agent station and the first drying station, and advancing the article through a second wash station between the second aqueous conductivity-enhancing agent station and the second drying station.

5. The method of any of embodiments 1 to 4, wherein the silver metal particles are dispersed within a hydrophilic binder.

6. The method of any of embodiments 1 to 5, wherein the aqueous solution comprises one or more conductivity enhancing agents in an amount of at least 0.1 weight % and up to and including 2.5 weight %.

7. The method of any of embodiments 1 to 6, comprising treating the silver metal particles with the aqueous solution comprising a conductivity enhancing agent that is at a temperature of at least 30° C. and up to and including 90° C.

8. The method of any of embodiments 1 to 7, comprising treating the silver metal particles with the aqueous solution comprising one or more conductivity enhancing agents in an amount of at least 0.5 weight % and up to and including 1.5 weight %, and the treating is at a temperature of at least 45° C. and up to and including 80° C.

9. The method of any of embodiments 1 to 8, comprising treating the silver metal particles with the aqueous solution comprising a conductivity enhancing agent for at least 0.25 minute and up to and including 30 minutes.

10. The method of any of embodiments 1 to 9, comprising washing the treated silver metal particles with the different aqueous solution that is water at a temperature of at least 30° C. and up to and including 50° C. for at least 30 seconds.

11. The method of any of embodiments 1 to 10, wherein the treating, optional washing, and drying treatment cycle were repeated for at least one additional treatment cycle.

12. The method of any of embodiments 1 to 11, wherein only the last additional treatment cycle includes washing with the different aqueous solution.

13. The method of any of embodiments 1 to 12, wherein each additional treatment cycle includes washing with the different aqueous solution.

14. The method of any of embodiments 1 to 13, wherein the aqueous solution comprising the conductivity enhancing agent comprises one or more sulfites, borane compounds, hydroquinones, p-phenylenediamines, or phosphites as one or more conductivity enhancing agents.

15. The method of any of embodiments 1 to 14, wherein the aqueous solution comprising the conductivity enhancing agent further comprises a primary or secondary organic amine compound.

16. The method of any of embodiments 1 to 15, wherein the aqueous solution comprising the conductivity enhancing agent has a pH of at least 6 and up to and including 11.

17. The method of any of embodiments 1 to 16, comprising providing the silver metal particles disposed on the substrate by developing an imagewise exposed photosensitive silver-containing salt disposed on the substrate.

18. The method of any of embodiments 1 to 17, comprising providing the silver metal particles disposed on the substrate in a predetermined pattern.

19. An article comprising the silver metal particles disposed on the substrate within a hydrophilic binder, as prepared according to the method of any of embodiments 1 to 18.

20. The article of embodiment 19, wherein the silver metal particles are disposed on the substrate within gelatin or a gelatin derivative.

The following Examples are provided to illustrate the practice of this invention and are not meant to be limiting in any manner.

### Examples

Conductive silver metal-containing films were prepared by exposing and processing a silver halide emulsion provided in a gelatin matrix on a 125 μm thick polyethylene terephthalate) (PET) film support. Two different silver halides were used in the silver halide emulsions.

Emulsion 1 comprised a silver halide comprised of 70 mol % silver chloride and 30 mol % silver bromide grains having cubic morphology and an edge length of 0.12 μm. The total silver cation coverage in Emulsion 1 was 4.5 g/m².

Emulsion 2 comprised a silver halide comprised of 100 mol % silver bromide grains of cubic morphology and an edge length of 0.08 μm. The total silver coverage in Emulsion 2 was 3.6 g/m².

The weight ratio of silver cations to gelatin in each emulsion was about 2.3:1. A UV-absorption layer was provided between the PET film support and the emulsion layer. BVSM [1,1′-(methylene(sulfonyl))bis-ethane] was coated at 0.5 weight % of total gelatin to harden each silver halide emulsion layer.

The resulting silver halide precursor elements were exposed using a chrome mask having a diamond-shaped grid pattern having corner-to-corner dimensions of 300 μM (vertical)×500 μm (horizontal). This grid pattern extended across a 1×1 inch (2.54 cm×2.54 cm) patch with solid contact pad areas at the upper and lower sides of the grid. The contact pad areas were 1 inch (2.54 cm) horizontal by 0.25 inches (0.63 cm) vertical. Two-point probe measurements were made on the 1×1 inch (2.54 cm×2.54 cm) grid using the contact pads in direct contact with that grid. The grid lines on the conductive film samples were approximately 3 μm wide.

The exposed silver halide films described above was processed to reduce the silver cations to silver metal using commercially available black and white photographic processing chemicals: 30 seconds of development using Kodak® ACCUMAX black-and-white developer, followed by 45 seconds of fixing using Kodak® Rapid Fix, 60 seconds of plain water washing, and 10 minutes for drying. These processing and washing steps were carried out at 40° C. and the drying was carried out at 50° C. Samples of silver halide films that were thus processed exhibited very high sheet resistance.

Some samples of the processed silver halide films, now containing silver metal, were then subjected to a single 10 minute treatment using an aqueous solution comprising a conductivity enhancing agent at 60° C., followed by a two minute plain water washing at 40° C., and a ten minute drying.

Other samples of the processed film were treated according to the present invention using two to five of the following treatment cycles: two minute treatments in the aqueous solution containing the conductivity enhancing agent at 60° C., followed by a two minute washing and ten minutes of drying. These repeated treatment cycles reduced the resistance in the silver metal-containing films (increased conductivity) below that of the silver metal-containing film that was treated only once. TABLE I below summarizes these various embodiments. TABLE II below describes the various aqueous solutions used to enhancing conductivity according to the present invention.

TABLE I
Photographic Processing and Conductivity Enhancing

| | | |
|---|---|---|
| | Temperature | |
| Chemical Solution | (° C.) | Time |

Photographic Processing (silver cations to silver metal)

| | | | |
|---|---|---|---|
| Kodak ® ACCUMAX Developer | 40 | 30 | seconds |
| Kodak ® Rapid Fix | 40 | 45 | seconds |
| Washing | 40 | 1 | minute |
| Drying | 50 | 10 | minutes |

Conductivity Enhancement Treatment (1 to 5 treatment cycles)

| Conductivity enhancing | 60 | See TABLE III below | |
|---|---|---|---|
| Washing | 40 | 2 | minutes |
| Drying | 50 | 10 | minutes |

TABLE II
Conductivity Enhancing Solutions

| | Components | pH |
|---|---|---|
| 1 | 1.0 mol/l of Na₂SO₃ | 10.3^{a} |
| 2 | 0.20 mol/l of dimethylamineborane | 10.2^{b} |
| 3 | 0.25 mol/l of hydroquinone + 0.50 mol/l of Na₂SO₃ | 10.2^{b} |
| 4 | 0.10 mol/l of 1,2-bis(3-aminopropylamino)ethane and | 10.6^{b} |
| | 0.06 mol/l of triethanolamine hydrochloride | |

^{a}No buffer
^{b}Buffer with 0.050 mol/l of Na₂CO₃ and 0.050 mol/l of NaHCO₃

The film resistance of each silver metal-containing film was measured using the two point probe attached to a general purpose ohmmeter (and thus, providing the inverse of conductivity) are shown below in TABLE III. These results demonstrate the advantage of carrying out at least two treatment cycles according to the present invention to using a single treatment cycle.

TABLE III

| | | Sheet Resistance (Ohms/square) | | | | | |
|---|---|---|---|---|---|---|---|
| | Conductivity- | | Single | | | | |
| | enhancing | | Cycle | Two | Three | Four | Five |
| | Solution | No | (10 | Treatment | Treatment | Treatment | Treatment |
| Element | TABLE II | treatment | minutes) | Cycles^{a} | Cycles^{a} | Cycles^{a} | Cycle^{a} |
| Comparative 1 | None | 38,720 | | | | | |
| (Emulsion 1) | | | | | | | |
| Comparative 2 | 1 | | 2,943 | 2,262 | 1,818 | 1,982 | 2,026 |
| (Emulsion 1) | | | | | | | |
| Invention 1 | 2 | | 700 | 382 | 357 | 345 | 317 |
| (Emulsion 1) | | | | | | | |
| Comparative 3 | None | >10⁶ | | | | | |
| (Emulsion 2) | | | | | | | |
| Invention 2 | 3 | | >10⁶ | >10⁶ | >10⁶ | 45,000 | 16,800 |
| (Emulsion 2) | | | | | | | |
| Invention 3 | 2 | | >10⁶ | >10⁶ | 985,000 | 16,000 | 1,100 |
| (Emulsion 2) | | | | | | | |
| Invention 4 | 4 | | >10⁶ | 35,000 | 4,800 | 2,235 | 1,491 |
| (Emulsion 2) | | | | | | | |

^{a}Two minutes for treatment with the conductivity enhancing agent for each treatment cycle

The invention has been described in detail with particular reference to certain preferred embodiments thereof, but it will be understood that variations and modifications can be effected within the spirit and scope of the invention.

### PARTS LIST

5 supply spool
15 exposed and processed silver-containing precursor element
25 web
70 take-up spool
110 substrate
120 imagewise exposed and processed photographic silver halide emulsion layer
125 hydrophilic binder
126a-f hydrophilic binder
127a-f printed areas
130a-f conductive traces
131a-f conductive silver metal nanoparticles
210 first set of stations
220 bath treatment station
230 drying station
235 treated conductive silver-containing element
240 second set of stations
265 additionally treated conductive silver-containing element

1. A method of improving the conductivity of silver disposed on a substrate, comprising:
providing silver metal particles disposed on a substrate,
treating the silver metal particles with an aqueous solution comprising a conductivity enhancing agent to provide treated silver metal particles,
optionally washing the treated silver metal particles with a different aqueous solution,
drying the treated and optionally washed silver metal particles to complete a first treatment cycle, and
repeating the treating, optional washing, and drying for at least one additional treatment cycle, in sequence, using the same or different conductivity enhancing agent, to improve the conductivity of the silver metal particles disposed on the substrate.

2. The method of claim 1, wherein the silver metal particles are dispersed within a hydrophilic binder.

3. The method of claim 1, wherein the aqueous solution comprises one or more conductivity enhancing agents in an amount of at least 0.1 weight % and up to and including 2.5 weight %.

4. The method of claim 1, comprising treating the silver metal particles with the aqueous solution comprising a conductivity enhancing agent that is at a temperature of at least 30° C. and up to and including 90° C.

5. The method of claim 1, comprising treating the silver metal particles with the aqueous solution comprising one or more conductivity enhancing agents in an amount of at least 0.5 weight % and up to and including 1.5 weight %, and the treating is at a temperature of at least 45° C. and up to and including 80° C.

6. The method of claim 1, comprising treating the silver metal particles with the aqueous solution comprising a conductivity enhancing agent for at least 0.25 minute and up to and including 30 minutes.

7. The method of claim 1, comprising washing the treated silver metal particles with the different aqueous solution that is water at a temperature of at least 30° C. and up to and including 50° C. for at least 30 seconds.

8. The method of claim 1, wherein the treating, optional washing, and drying treatment cycle were repeated for at least one additional treatment cycle.

9. The method of claim 8, wherein only the last additional treatment cycle includes washing with the different aqueous solution.

10. The method of claim 8, wherein each additional treatment cycle includes washing with the different aqueous solution.

11. The method of claim 1, wherein the aqueous solution comprising the conductivity enhancing agent comprises one or more sulfites, borane compounds, hydroquinones, p-phenylenediamines, or phosphites as one or more conductivity enhancing agents.

12. The method of claim 1, wherein the aqueous solution comprising the conductivity enhancing agent further comprises a primary or secondary organic amine compound.

13. The method of claim 1, wherein the aqueous solution comprising the conductivity enhancing agent has a pH of at least 6 and up to and including 11.

14. The method of claim 1, comprising providing the silver metal particles disposed on the substrate by developing an imagewise exposed photosensitive silver-containing salt disposed on the substrate.

15. The method of claim 1, comprising providing the silver metal particles disposed on the substrate in a predetermined pattern.

16. An article comprising the silver metal particles disposed on the substrate within a hydrophilic binder, as prepared according to the method of claim 1.

17. The article of claim 16, wherein the silver metal particles are disposed on the substrate within gelatin or a gelatin derivative.

18. A method for improving the conductivity of silver metal particles, comprising:
providing an article comprising a hydrophilic layer disposed on a substrate, the hydrophilic layer comprising silver metal particles dispersed within a hydrophilic binder,
advancing the article through a first set of stations including, in sequence, a first aqueous conductivity-enhancing agent station and a first drying station separated from the first aqueous conductivity-enhancing agent station, and
advancing the article from the first set of stations through a second set of stations including, in sequence, a second aqueous conductivity-enhancing agent station and a second drying station spaced from the second aqueous conductivity-enhancing agent station.

19. The method of claim 18, further comprising:
advancing the article through a first washing station between the first aqueous conductivity-enhancing agent station and the first drying station, or
advancing the article through a second wash station between the second aqueous conductivity-enhancing agent station and the second drying station, or
both advancing the article through a first washing station between the first aqueous conductivity-enhancing agent station and the first drying station, and advancing the article through a second wash station between the second aqueous conductivity-enhancing agent station and the second drying station.

20. The method of claim 19, further comprising:
both advancing the article through a first washing station between the first aqueous conductivity-enhancing agent station and the first drying station, and advancing the article through a second wash station between the second aqueous conductivity-enhancing agent station and the second drying station.
